(19) United States
(12) Patent Application Publication
(10) Pub. No.: US 2025/0130259 A1
(43) Pub. Date: Apr. 24, 2025

(54) POWER PROBE FIXTURES AND ADAPTERS

(71) Applicant: Tektronix, Inc., Beaverton, OR (US)

(72) Inventor: John J. Pickerd, Hillsboro, OR (US)

(73) Assignee: Tektronix, Inc., Beaverton, OR (US)

(21) Appl. No.: 18/924,900

(22) Filed: Oct. 23, 2024

Related U.S. Application Data
(60) Provisional application No. 63/592,523, filed on Oct. 23, 2023.
(60) Provisional application No. 63/560,163, filed on Mar. 1, 2024.

(51) Int. Cl. G01R 21/06; G01R 1/067; G01R 15/12

(52) U.S. Cl. CPC G01R 21/06; G01R 1/067; G01R 15/125

(57) ABSTRACT

A universal power probe fixture (UPPF) that is configured to be installed into a power signal path between a source device and a load device has one or more UPPF base modules, each UPPF base module including an input terminal block, an output terminal block, and a power transfer circuit including a multiple signal lines electrically connected between the input terminal block and the output terminal block, the signal lines structured to convey high power, and each of the signal lines includes a current probe connection point and at least one voltage probe connection point. The UPPF also has a source device connector adapted to electrically connect the source device to the input terminal block, and a load device connector adapted to electrically connect the load device to the output terminal block. A test system using the UPPF, and an application-specific electric vehicle motor probe adapter are also disclosed.

### CROSS-REFERENCE TO RELATED APPLICATIONS

This application claims the benefit of U.S. Prov. Pat. App. No. 63/592,523, titled “EV MOTOR PROBE ADAPTOR,” filed Oct. 23, 2024, and U.S. Prov. Pat. App. No. 63/560,163, titled “UNIVERSAL POWER PROBE FIXTURE,” filed Mar. 1, 2024. The entire contents of each of these prior-filed applications is hereby incorporated by reference into this disclosure.

### TECHNICAL FIELD

This disclosure relates to test and measurement systems, and more particularly to fixtures, adaptors, and accessories for connecting probes between a device under test (DUT) and a test and measurement instrument such as an oscilloscope.

### BACKGROUND

An oscilloscope probe is a device that makes a physical and electrical connection between a test point or signal source and an oscilloscope. Depending on your measurement needs, this connection can be made with something as simple as a length of wire or with something as sophisticated as an active differential probe. Essentially, a probe is a device or network connecting the signal source to the oscilloscope's input. An oscilloscope probe provides a quality connection between the signal source—or device under test (DUT)—and an oscilloscope. There are several important considerations when choosing and using an oscilloscope probe, including the physical attachment, impact on circuit operation, and signal transmission.

High power systems or DUTs, such as industrial robots, solar power installations, or electric vehicle (EV) motor systems, can be difficult to probe in practice because these systems and DUTs are often sealed to the external environment, making it challenging to physically connect a probe to the DUT. Embodiments of the disclosure address these and other challenges.

### BRIEF DESCRIPTION OF THE DRAWINGS

FIG. 1 is a system diagram of an example test system including a Universal Power Probe Fixture (UPPF), according to some embodiments of the disclosure.

FIG. 2 is a block diagram of a UPPF base module, according to some embodiments of the disclosure.

FIG. 3 is a diagram of an example PCB layout for a UPPF base module, according to some embodiments of the disclosure.

FIG. 4 is a diagram of a UPPF with probes connected, according to some embodiments of the disclosure.

FIG. 5 is a system diagram of an example test system including a UPPF, according to some embodiments of the disclosure.

FIGS. 6A-6E are examples of a user interface for configuration of power analysis software to be used with the UPPF, according to some embodiments of the disclosure.

FIG. 7 is a diagram of an EV motor probe adaptor, according to some embodiments of the disclosure.

FIG. 8 is a diagram of an EV motor probe adaptor connected to a cable, according to some embodiments of the disclosure.

FIG. 9 is a diagram of an EV motor neutral cable probe adaptor, according to some embodiments of the disclosure.

FIG. 10 is a diagram of an EV motor probe adaptor connected between an inverter and an EV motor, with probes connected, according to some embodiments of the disclosure.

### DETAILED DESCRIPTION

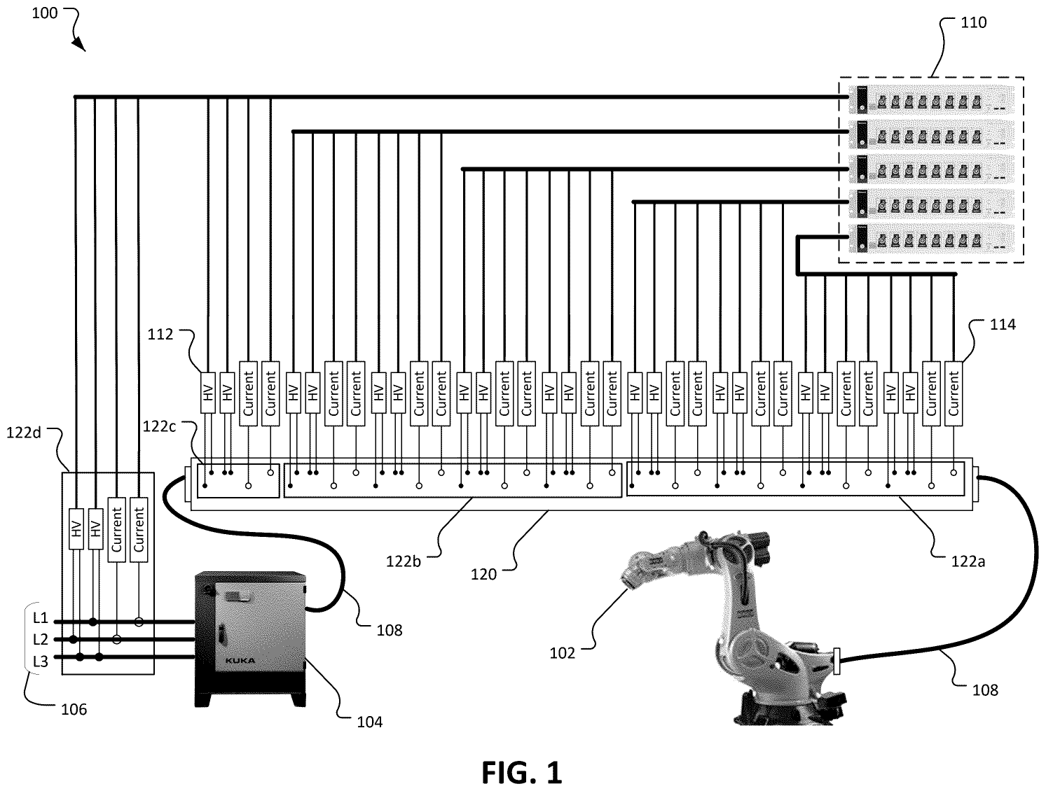

Embodiments of the disclosure are generally intended to be used in test systems for high power applications, such as performing power measurements on industrial robots, industrial motors, electric vehicles, solar panel installations, etc., as just a few non-limiting examples of potential applications. The discussion below refers to some embodiments of the disclosure as a Universal Power Probe Fixture (UPPF). FIGS. 1-6 generally illustrate aspects of a UPPF, according to some embodiments of the disclosure. In general, a UPPF, according to embodiments of the disclosure, is structured to interface voltage and/or current probes to one or more phases of power signals.

Embodiments of a UPPF are intended for use in a test system, together with the following Tektronix test and measurement instruments, probes, and analysis software, or similar components: a single MSO58B oscilloscope (see https://www.tek.com/en/products/oscilloscopes/5-series-mso), or many MSO58LP oscilloscopes in a single rack (see https://www.tek.com/en/products/oscilloscopes/high-speed-digitizers/5-series-mso-low-profile), with many TCP0030A high current probes (see https://www.tek.com/en/products/oscilloscopes/oscilloscope-probes/current-probes), and many THDP0100 high voltage probes (see https://www.tek.com/en/products/oscilloscopes/oscilloscope-probes/high-voltage-differential-probes), IMDA (Inverter Motor Drive Analysis) Software (see https://www.tek.com/en/datasheet/inverter-motor-drive-analysis-5series-mso-option-5-imda-application-datasheet), and a new Electric Motor Vector Analyzer (EMVA)/Power Vector Analyzer (PVA) plugin software module for the oscilloscope. U.S. patent application Ser. No. 18/914,685, titled “POWER VECTOR ANALYZER,” filed Oct. 14, 2024, the contents of which are hereby incorporated by reference into this disclosure, describes embodiments and capabilities of a EMVA/PVA software module, which produces a display showing dynamic changes in apparent power, with phase angle, indicative of impedance and the direction the power is flowing in the system. Such a display may also be referred to as an impPower™ display.

The UPPF supports other probe models besides Tektronix probes, as well, since it is “universal.” The UPPF can support power measurement applications ranging from a single 120 VAC supply line, to a robot with up to twenty 3-phase motors.

One particular example application for some embodiments of the disclosure is shown in FIG. 1. A test system 100, as illustrated in FIG. 1, includes a device under test (DUT) 102, numerous probes 112, 114, and a test and measurement instrument 110 for acquiring voltage and current signals from the DUT 102 through the probes 112, 114. The DUT 102 may be a high-powered industrial robot, which is a KUKA KR1000 titan robot arm in this example. This robot can lift 1.3 tons and uses a maximum of 88 kW of power. Like other industrial robots, this robot uses multiple high power motors, specifically nine motors for this particular model, as detailed in Table 1:

TABLE 1

| Motor # | Name | Power (kW) | Frequency Range (Hz) |
|---|---|---|---|
| 1 | Base rotation | 28 | 0 to 30 |
| 2 | Lower arm | 7.5 | 0 to 1000 |
| 3 | Upper arm | 7.5 | 0 to 1000 |
| 4 | Forearm | 7.5 | 0 to 1000 |
| 5 | Wrist 1 | 7.5 | 0 to 1000 |
| 6 | Wrist 2 | 7.5 | 0 to 1000 |
| 7 | Wrist 3 | 7.5 | 0 to 1000 |
| 8 | Gripper | 7.5 | 0 to 1000 |
| 9 | Axis 2 | 7.5 | 0 to 1000 |

The example system 100 shown in FIG. 1 measures complex dynamic power of all nine motors on the DUT 102. To do so, the system 100 uses a total of forty probes, and five 8-channel MSO58LP rack mount oscilloscopes 110. Each probe, such as the twenty high voltage differential probes (“HV”) 112, and the twenty high current probes (“Current”) 114, is connected to one channel of one of the five 8-channel oscilloscopes 110. The five 8-channel oscilloscopes are synchronized and linked together to essentially form a 40-channel oscilloscope 110, according to methods and technology known in the art. See, e.g., https://www.tek.com/en/documents/technical-brief/how-to-synchronize-4-5-and-6-series-mso-oscilloscopes-for-higher-channel-count. User input and control of the oscilloscope 110 and viewing a display of measurement results and analysis may be through either one or both of the oscilloscope's built in display and processors, or an external PC and/or display device (not shown).

Probing the high voltage on the order of 800Vpp and the high currents as high as 700A poses difficulty in attaching probes and maintaining safety. Probes need to be attached without modifying or damaging the existing connections on a DUT, such as between a 3-phase inverter and an EV motor. This is also true for the robots which similarly use a variable frequency inverter to drive its 3-phase motors, such as the robot DUT 102 in FIG. 1. More generally, the probes need to be placed between the source of power and the load.

In addition, depending on the specific connection there may be one Differential High Voltage (HV) probe connection and one current probe connection on one line. In a normal connection sealed from the environment there is no point available to make direct connection of the voltage probes.

Embodiments of the disclosure include a universal power probe fixture, UPPF, which contains three power transfer circuits, each capable of supporting three phase, single phase, and 240 Vac lines. Multiple base modules of the UPPF may be incorporated to handle as many power transfer circuits as needed for any given application. Some embodiments of the disclosure are application-agnostic. A base module UPPF, according to embodiments of the disclosure, can also handle three branch bidirectional power transfers in home solar panel installations.

As shown in FIG. 1, the system 100 includes a UPPF 120, according to embodiments of the disclosure. The UPPF 120 provides a convenient and user-friendly way to connect the probes 112, 114 to the signal lines to be measured in the DUT 102. In the example of FIG. 1, the signal lines to be measured are three-phase power signals (voltage and current) between each of the nine motors on the robot DUT 102 and the robot controller 104, as well as the incoming 3-phase power lines 106 that supply power to the controller 104. The controller 104 in this example may be a KUKA KR-C4 extended controller. The controller 104 uses the input power 106 to power each 3-phase motor in the robot DUT 102. Thus, there are three power lines for each motor that can be measured in the connection 108 between the controller 104 and the DUT 102. The connection 108 may include, for example, a KUKA Cabler. When not needing to measure or monitor the power signals, the controller 104 may be connected directly to the DUT 102 through the connection 108. However, to measure or monitor the power signals, the UPPF 120 may be inserted as a part of the connection 108. Therefore, the UPPF 120 forms a portion of the power transmission path between the controller 104 and the DUT 102, and also provides convenient probing points for measuring the power signals flowing between the controller 104 and the DUT 102 in operation.

As discussed in more detail below, the UPPF 120 may be configured to support any number of probes and/or power lines to be measured by using a selectable number of UPPF base modules 122a-122d. In the example system 100 shown in FIG. 1, the UPPF 120 includes a group of three UPPF base modules 122a, 122b, 122c. The system 100 also uses a fourth UPPF base module 122d for measuring input power 106 to the inverter/controller 104. As discussed further below, UPPF base modules 122c and 122d do not use all of the possible probe connection points included in a UPPF base module. This configuration shown in FIG. 1 allows for forty probes to be connected to monitor total power into the system, and instantaneous impPower™ display of power simultaneously for all nine of the robot 102 3-phase motors.

### Base Module UPPF Circuit Configuration:

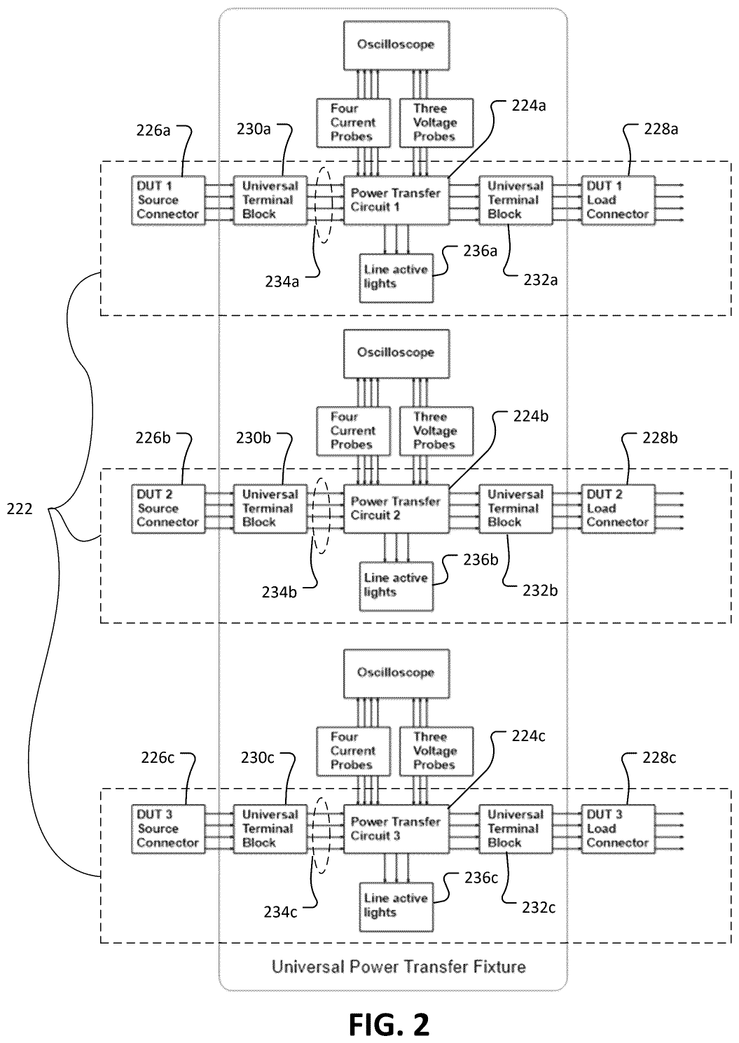

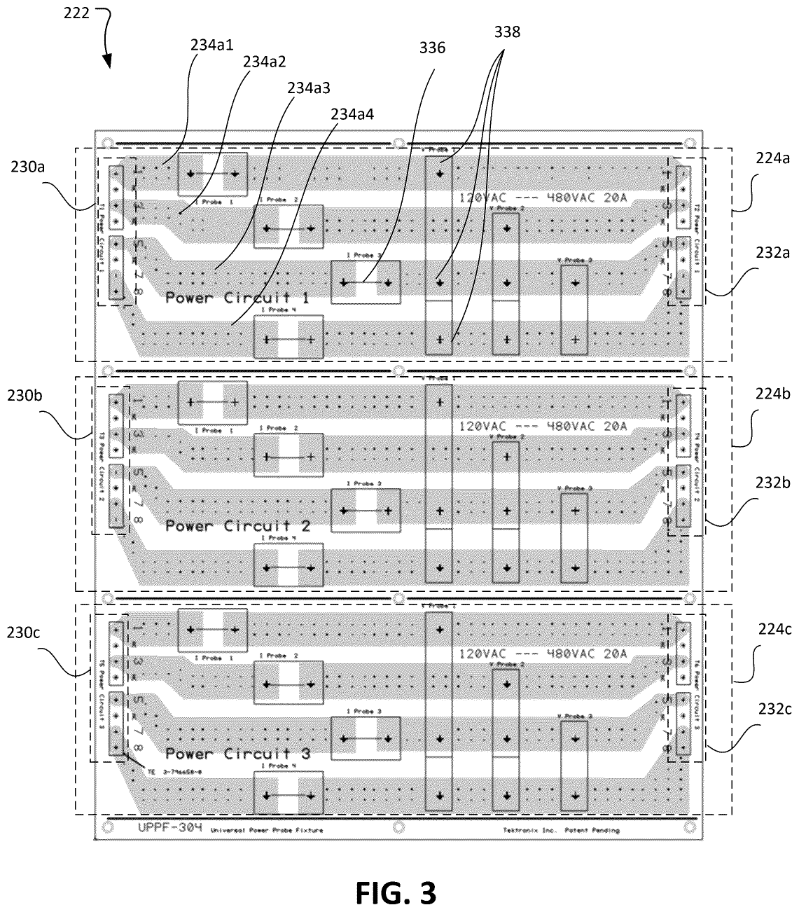

Refer to FIG. 2, showing a block diagram of an example UPPF base module 222, and FIG. 3, showing an example PCB layout for the UPPF base module 222, according to embodiments of the disclosure. The UPPF base modules 122a-122d in FIG. 1 may be examples of the UPPF base module 222 shown in FIG. 2. The UPPF base module 222 includes the components shown within the three dashed line rectangles in FIG. 2, but excludes the voltage and current probes, and the oscilloscopes, which are shown in FIG. 2 for context. The UPPF base module 222 is configured with three power transmission/power transfer circuits 224a-224c. Each power transfer circuit 224a-224c transfers power from the respective source connector 226a-226c to the respective load connector 228a-228c. Each power transfer circuit 224a-224c may have a respective terminal block input 230a-230c on one side of the PCB and a respective terminal block output 232a-232b on another side of the PCB. Each power transfer circuit 224a-224c circuit has four circuit lines 234a-234c. As an example, the four lines 234a of power transfer circuit 224a are labeled as lines 234a1, 234a2, 234a3, and 234a4 in FIG. 3. As shown in FIG. 3, the PCB traces for these lines are relatively large, since these lines will generally carry high voltage and large currents. Some applications would use all four lines, e.g. three phases of power lines plus one neutral, and some applications may use only one neutral and one power line. This allows the UPPF to handle most types of power transfer systems from single phase to 3-phase. This includes 120 VAC single phase, 3-phase system either delta or wye connections. The user of the UPPF will only connect the available circuits as needed for the probing system they are putting together. Having four lines makes the system universal so that it can handle all of the primary use case that are supported for power measurement and analysis. In some embodiments, each power transfer circuit 224a-224c may also include line active lights 236a-236c, which may be, for example, LEDs that indicate when power is flowing in one of the respective lines 234a-234c.

The power transfer circuits 224a-224c also provide locations for connecting voltage and/or current probes. As shown best in FIG. 3, each of the four lines 234a-234c may contain a place for a current probe connection. An example of a current probe connection location 336 is shown in FIG. 3 for line 234a3 of power transfer circuit 224a. As shown in FIG. 3, there may be a cutout in the circuit board, i.e. a gap in the power line, and a jumper wire across it for clamp-on probe. Or, in other embodiments, there may be a banana jack at each end of the gap and an external jumper wire may be plugged in for clamp-on current probes. In some embodiments, the jumper wire may be unplugged, and an inline current meter may replace the short jumper. To connect voltage probes, each of the lines 234a-234c may also include one or more locations, such as locations 338, for example, for a probe connector, such as a banana jack to be placed. There are multiple banana jacks on the various lines to support the various types of probe connections that are discussed further below. As shown in FIG. 3, these probe connections can support differential and/or single-ended voltage probe connections.

As shown in FIGS. 2-3, each UPPF base module 222 supports three power transfer circuits, and up to 12 or more probes. For any applications such as robots that may have 5 to 20 three-phase motors, the user may incorporate as many UPPF base modules 222 as are needed into an integrated UPPF fixture 120.

It should be noted that the circuit board implementation shown in FIG. 3 is only one possible implementation that would support a wide variety of applications. However, note that some applications requiring even higher power may have different connectors and different size traces or layout configuration. However, they would still contain the same basic elements as the example shown.

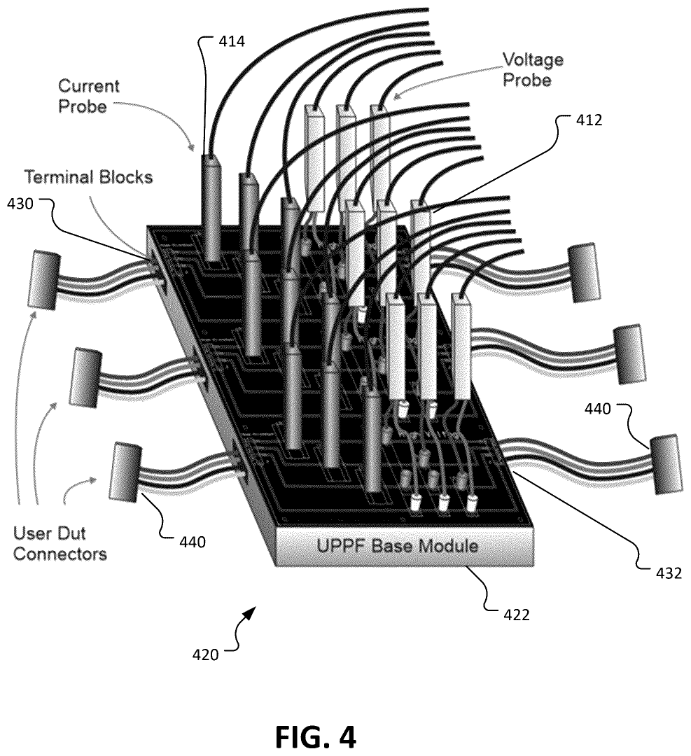

Refer to FIG. 4 showing how a UPPF 420 can be configured with many probes 412, 414 which would connect to the UPPF 420 at the probe tip, and an oscilloscope channel at the other end. The example UPPF 420 shown in FIG. 4 uses only a single UPPF base module 422, but, as discussed above, other embodiments of a UPPF may use multiple base modules, according to embodiments of the disclosure. The illustrated example shows nine voltage probes 412 and nine current probes 414 connected to the three power transfer circuits of the UPPF. FIG. 4 illustrates how the terminal blocks 430, 432 facilitate a wire interface 440 between the DUT connectors and the UPPF 420. That is, the terminal blocks 430, 432 provide the ability to easily interface with any type of power connector that the DUT system may employ, with wire connections between the terminal block(s) and the power connector(s). This allows the UPPF 420 to interface with either commercial off-the-shelf power connectors, or custom connector types. Therefore, the UPPF 420 is universal, not depending on the many types of power connectors that various systems might incorporate. Notice the UPPF unit 420 as pictured can easily and quickly be removed from the DUT system. This can facilitate manufacturing line testing of the DUT systems.

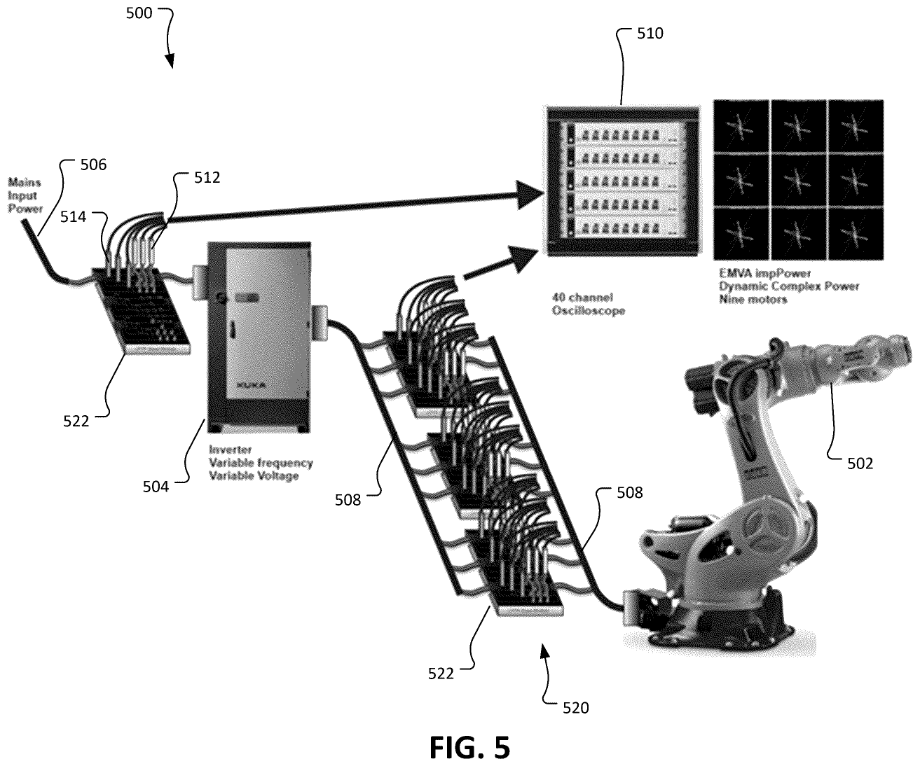

Refer to FIG. 5 showing another example test system 500, similar to the test system 100 shown in FIG. 1. FIG. 5 shows how a UPPF 520 using four of the UPPF base modules 522 can be incorporated using forty probes 512, 514 into five 8-channel oscilloscopes 510. This facilitates measuring the input power to the inverter 504 that drives the robot 502, and it facilitates simultaneously measuring all nine 3-phase motors on this robot, via cable connections 508, as in the example system 100 of FIG. 1.

### Probe Configuration Options:

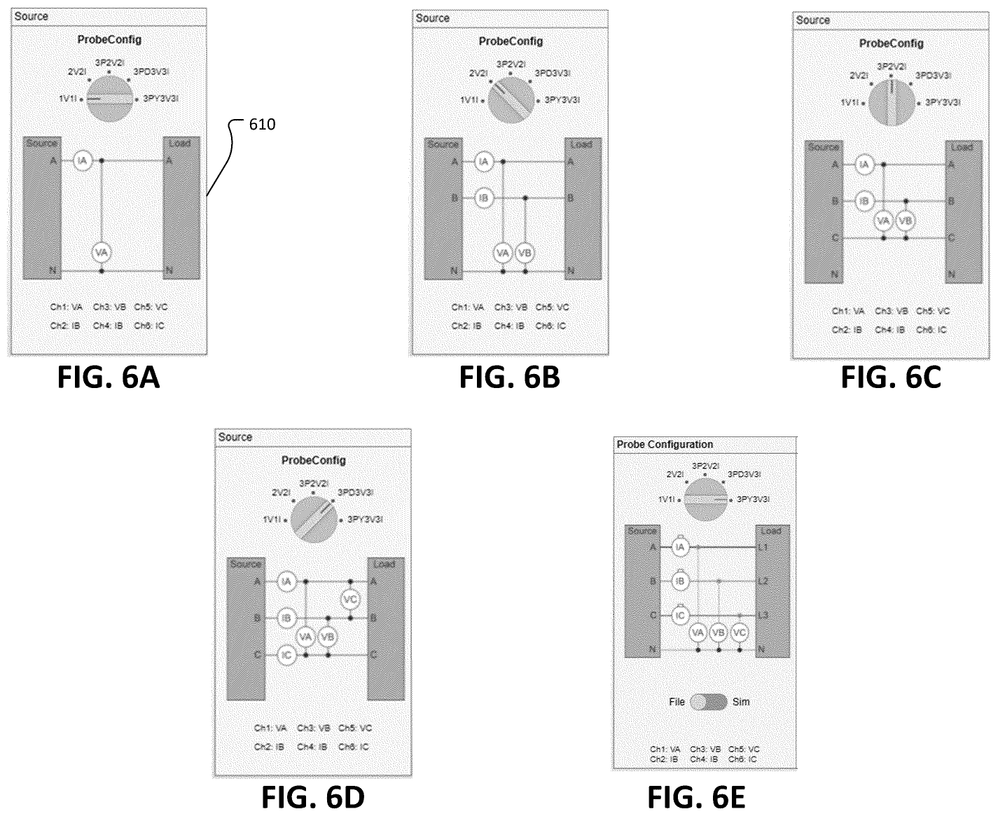

As discussed above with respect to FIGS. 2 and 3, the UPPF contains banana or other connectors for probe connections points. Given the four power line circuit lines in each of the probable power transmission paths, the different probing configurations shown in FIGS. 6A-6E are supported. FIG. 6A shows a user interface menu 610 set to a configuration (“1V1I”) for one voltage signal/probe and one current signal/probe. FIG. 6B shows the user interface menu 610 set to a configuration (“2V2I”) for two voltage signals/probes and two current signals/probes. FIG. 6C shows the user interface menu 610 set to a configuration (“3P2V2I”) for a three-phase power connection with two voltage signals/probes and two current signals/probes. FIG. 6D shows the user interface menu 610 set to a configuration (“3PD3V3I”) for a three-phase delta connection with three voltage signals/probes and three current signals/probes. FIG. 6E shows the user interface menu 610 set to a configuration (“3PY3V3I”) for a three-phase wye connection with three voltage signals/probes and three current signals/probes. The EMVA, PVA, or IMDA power analysis software applications would contain menus similar to those shown in FIGS. 6A-6E to select the appropriate probe connection configuration for the DUT system being measured. The UPPF base module supports all these line and probe configurations. Therefore, it supports a wide range of power transfer applications.

The discussion above has described a UPPF, universal power probe fixture, that has the ability to connect voltage and current probes to multi power branch applications. Examples are dual EV motor analysis, three branch solar power system that need bidirectional power measurement. It can also handle robot systems, where 9 to 20 3-phase motors can all be monitored simultaneously for dynamic instantaneous complex power analysis. Embodiments enable power analysis software to provide a unique impPower™ view for this analysis. The novel circuit configuration of this module makes it universal because terminal blocks allow the user to make a connector adapter harness that plugs into their DUT directly and then into the terminal block. This allows quick connect and disconnect to monitor a system for test. This is ideal for testing on a manufacturing line because it is easy to quickly insert the fixture into the user DUT system, and easily remove it when completed, without any need to modify the user DUT. Thus, any type of DUT connectors, are handled by the user wiring to the terminal blocks. It isolates test and measurement instrument and probe manufacturers from having to know about and support an endless number of customer DUT connector schemes. And it allows one base module to be used for many different types of applications and connector systems. The pluggable current loop allows for either inline current meters or clamp on current probes to be used. Another aspect that makes it universal is that each power transmission circuit has four lines with multiple probe and current connection points. Only the lines needed for a particular application will be connected into the system. In addition, the multiple jacks for probes on these lines are configured to give options to support any of the possible probing configurations described in this disclosure.

### EV Motor Probe Adaptor:

While the UPPF discussed above is structured to be usable in numerous different applications, still other embodiments of the disclosure include an adaptor specifically structured to provide probe connection points between an inverter and an EV motor. Typically, an inverter delivers power to an EV motor via multiple insulated, high-power cables.

Probing the high voltage on the order of 800Vpp and the high currents as high as 700 Arms flowing in these connections between an inverter and an EV motor poses difficulty in attaching probes and maintaining safety. Probes need to be attached without modifying or damaging the existing connections between a 3-phase inverter and an EV motor.

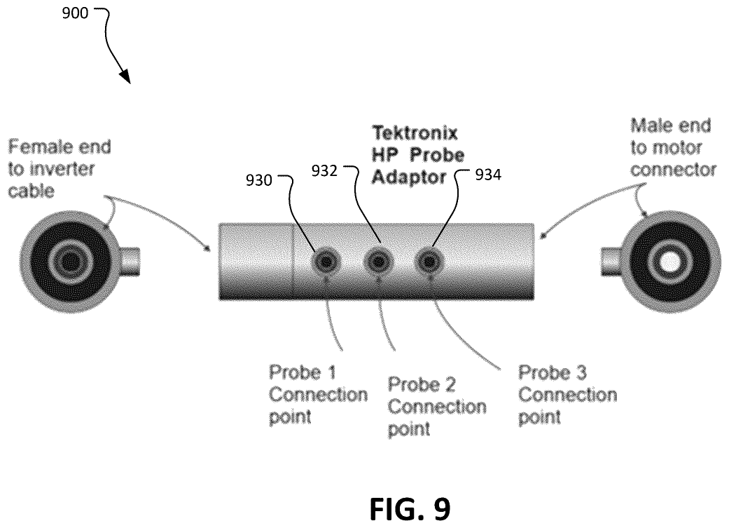

In addition, depending on the specific connection there may be two different high voltage probe connections and one current probe connection on one line/cable. In a normal connection sealed from the environment there is no point available to make direct connection of the voltage probes. Current probes may be connected assuming their loop size is large enough to fit around the insulated cable. Therefore, what is needed is the specific HV and current probe adaptor that facilitates two HV probe connections, and one current probe connection from one adapter for one cable. A 3-phase motor with a 3-wire connection would require three of these adaptors in order to connect all six probes. A four wire connection would require an additional neutral high power adaptor as shown in FIG. 9.

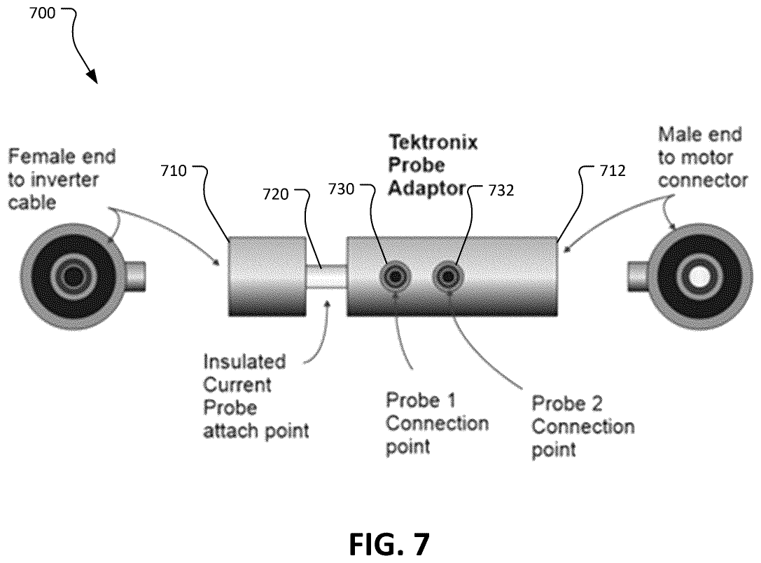

FIG. 7 shows an embodiment of a high-power (HP) probe adaptor cable assembly 700, according to some embodiments of the disclosure. The HP probe adapter 700 has a generally cylindrical form factor. The HP probe adaptor 700 configured as a cable assembly may have either removable or permanently attached cables at the HP adaptor port interface(s); that is, at an inverter connector 710, and/or at a motor connector 720. Removable may be preferred as that may allow for the motor and inverter ports to have different types of connectors. The inverter connector 710 will typically be a female connector, and the motor connector 712 will typically be a male connector. The HP probe adaptor 700 includes two voltage probe connection points 730, 732, and one current probe connection point 720. The voltage probe connection points 730, 732, may be any type of suitable high-voltage connector. The current probe connection point 720 may comprise a portion of the probe adapter body with a smaller cross-sectional area to allow a clamp-on current probe to encircle a current-carrying wire running through that portion of the adapter 700. This portion of the adapter may be covered with insulating material, but the insulating material may be thinner in this portion of the adapter to allow a current probe to easily fit around the conductor.

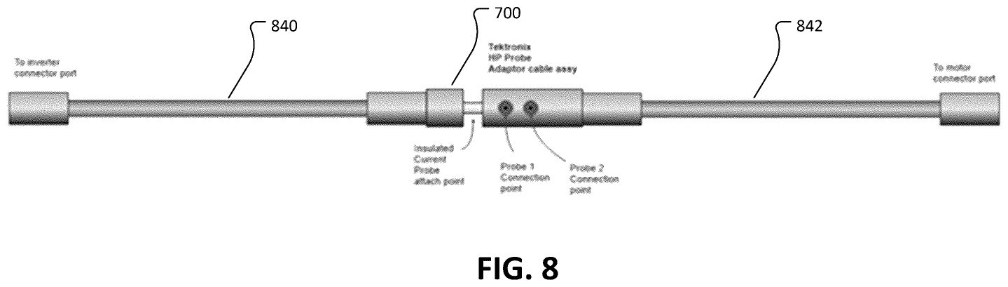

FIG. 8 shows the HP probe adapter 700 with a cable 840 attached at the inverter connector 710, and a cable 842 attached at the motor connector.

As shown in FIG. 9, an alternative embodiment of an HP probe adaptor 900 has three voltage probe connections 930, 932, 934, and no current probe connections. This adaptor 900 may be used in the 3-phase four-wire connection and inserted into the neutral line. This version of the HP probe adapter may also be used with adaptor cables.

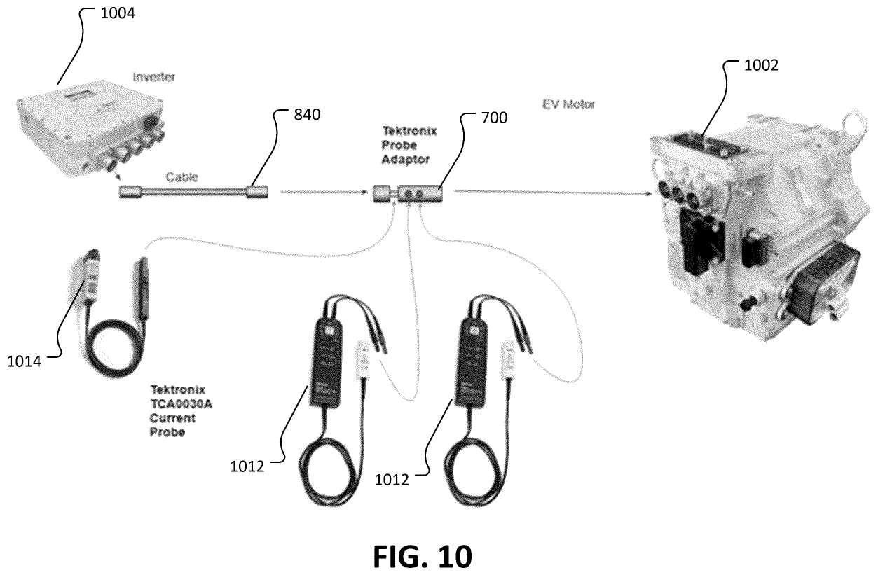

FIG. 10 illustrates portions of an example test system 1000, according to some embodiments of the disclosure. Test system 1000 includes an inverter 1004, an EV motor 1002, and one or more of the HP probe adapter 700 of FIG. 7. The inverter 1004 is connected to the HP probe adapter 700 by a cable 840. As shown in FIG. 10, the HP probe adapter 700 is connected directly to a connector on the EV motor 1002, but there may also be a cable making this connection in other configurations. The test system 100 also includes a current probe 1014 interfaced to the current probe connection point of the HP probe adapter 700, and one or more voltage probes 1012 connected to the voltage probe connection point(s) of the HP probe adapter 700. The output of the each probe is connected to a separate input of a test and measurement instrument (not shown), such as a multi-channel oscilloscope. Typically, one HP adaptor is used for each power cable input to the motor.

Power analysis software being used in conjunction with embodiments of the HP probe adapters 700, 900 would use similar probe configuration options as shown in FIGS. 6a-6E as discussed above.

One aspect of embodiments of an HP probe adapter is its new form factor.

Another aspect of embodiments of an HP probe adapter is its cylindrical body shape that can plug into existing motor input ports.

Another aspect of embodiments of an HP probe adapter is its insulated body to protect against high voltage on the order of up to 800 Vrms or more.

Another aspect of embodiments of an HP probe adapter is its current probe connection slot, which may be wide enough so a current probe can clamp around the cable conductor. In one embodiment, the conductor may have thin insulation inside the slot. In other embodiments only one current slot probe is needed.

Another aspect of embodiments of an HP probe adapter is providing a motor connector port.

Another aspect of embodiments of an HP probe adapter is provisioning an inverter connector port.

Another aspect of embodiments of an HP probe adapter is its ability to provide at least two high voltage probe connector ports, which may allow for connecting one or two high voltage probe leads to the cable input to the motor.

Another aspect of embodiments of an HP probe adapter is that ports are protected from exposure to high voltage by the person setting up the probe configuration.

Another aspect of embodiments of an HP probe adapter is that the above ports of the high-power adaptor may be any type of connector as needed for the inverter, motor, and probes.

Another aspect of embodiments of an HP probe adapter is that it allows for three probe adaptor configurations even if there are no current probe slots for three high voltage probe ports for 3-phase 4-wire systems the neutral connection of probes.

Another aspect of embodiments of an HP probe adapter is the provisioning of adaptor labels wherein the high-power (HP) adaptor may have a label of A, or B, or C, or N for neutral, or other similar notations.

Another aspect of embodiments of an HP probe adapter is the HP probe adaptor cable assembly itself. This may be in the form factor of a cable with the adaptor in between. Alternatively, this may be two short cables attached to each end. In some embodiments, the cables may have their connector ports that plug into the HP adaptor, as one embodiment is shown in FIG. 8. Alternatively, the cable assembly may be fixed so that one or more cables are not removable from the HP adaptor.

Aspects of the disclosure may operate on a particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

Additionally, this written description makes reference to particular features. It is to be understood that the disclosure in this specification includes all possible combinations of those particular features. For example, where a particular feature is disclosed in the context of a particular aspect, that feature can also be used, to the extent possible, in the context of other aspects.

Also, when reference is made in this application to a method having two or more defined steps or operations, the defined steps or operations can be carried out in any order or simultaneously, unless the context excludes those possibilities.

Although specific aspects of the disclosure have been illustrated and described for purposes of illustration, it will be understood that various modifications may be made without departing from the spirit and scope of the disclosure.

What is claimed is:

1. A universal power probe fixture (UPPF) configured to be installed into a power signal path between a source device and a load device, the UPPF comprising:
one or more UPPF base modules, each UPPF base module including
an input terminal block,
an output terminal block, and
a power transfer circuit including a plurality of signal lines electrically connected between the input terminal block and the output terminal block, the signal lines structured to convey high power, wherein each of the signal lines includes a current probe connection point and at least one voltage probe connection point;
a source device connector adapted to electrically connect the source device to the input terminal block; and
a load device connector adapted to electrically connect the load device to the output terminal block.

2. The UPPF according to claim 1, wherein each UPPF base module includes three input terminal blocks, three output terminal blocks, and three power transfer circuits.

3. The UPPF according to claim 1, wherein the input terminal block and the output terminal block comprise screw-down terminal blocks.

4. The UPPF according to claim 1, wherein the power transfer circuit includes four signal lines.

5. The UPPF according to claim 4, wherein a first signal line of the four signal lines provides a power signal path for a first phase of a three-phase power signal between the source device and the load device, a second signal line of the four signal lines provides a power signal path for a second phase of a three-phase power signal between the source device and the load device, and a third signal line of the four signal lines provides a power signal path for a third phase of a three-phase power signal between the source device and the load device.

6. The UPPF according to claim 5, wherein a fourth signal line of the four signal lines provides a power signal path for a neutral line of a three-phase power signal between the source device and the load device.

7. The UPPF according to claim 1, wherein the signal lines are implemented as traces on a printed circuit board (PCB) structured to carry currents greater than 700 A.

8. The UPPF according to claim 7, wherein the traces are structured to carry currents greater than 1 kA.

9. The UPPF according to claim 1, wherein the current probe connection point comprises a gap in the signal line.

10. The UPPF according to claim 9, wherein the current probe connection point further comprises a jumper wire electrically connected to the signal line across the gap, the jumper wire structured to enable a current probe to encircle the jumper wire.

11. The UPPF according to claim 9, wherein the current probe connection point further comprises a connector electrically connected to the signal line on each side of the gap.

12. The UPPF according to claim 11, wherein the connector is structured to accept one of a removable jumper wire electrically connected to the signal line across the gap, or a series current probe electrically connected to the signal line across the gap.

13. The UPPF according to claim 1, wherein the voltage connection point comprises a connector structured to interface with a high-voltage probe.

14. The UPPF according to claim 13, wherein the connector comprises a banana jack.

15. The UPPF according to claim 1, wherein the power transfer circuit includes a number of voltage connection points on the plurality of signal lines to allow differential voltage measurements between each of the plurality of signal lines.

16. The UPPF according to claim 1, wherein the UPPF base module further includes one or more line active indicators, each line active indicator configured to indicate to a user when a respective signal line is energized.

17. A test system, comprising:
a source device;
a load device including one or more three-phase motors;
one or more power signal paths between the source device and each of the respective one or more three-phase motors of the load device;
a Universal Probe Power Fixture (UPPF) forming a portion of each power signal path, the UPPF including one or more UPPF base modules, each UPPF base module including
an input terminal block,
an output terminal block, and
a power transfer circuit including a plurality of signal lines electrically connected between the input terminal block and the output terminal block, the signal lines structured to convey high power, wherein each of the signal lines includes a current probe connection point and at least one voltage probe connection point;
a source device connector adapted to electrically connect the source device to the input terminal block;
a load device connector adapted to electrically connect the load device to the output terminal block;
at least one high voltage probe for each phase of each of the three-phase motors of the load device, each high voltage probe connected to one of the voltage probe connection points;
at least one current probe for each phase of the three-phase motors of the load device, each current probe connected to one of the current probe connection points; and
a test and measurement instrument having a number of input channels, each input channel connected to the output of one of the high voltage probes or the current probes, the test and measurement instrument configured to simultaneously acquire voltage signals from the each of the high voltage probes and current signals from each of the current probes.

18. The test system according to claim 17, further comprising power analysis software configured to use the voltage signals and the current signals to compute dynamic instantaneous complex power for each of the three-phase motors of the load device.

19. An electric vehicle probe adapter assembly for establishing an electrical connection between an inverter and an electric motor, comprising:
a body;
an inverter connector at a first end of the body;
a motor connector at an opposite end of the body;
a power signal path between the inverter connector and the motor connector;
a current probe connection point, the current probe connection point structured to allow a current probe to sense a current flowing in the power signal path; and
a high-voltage probe connection point, the high-voltage probe connection point structured to allow a high-voltage probe to sense a voltage between two conductors in the power signal path.

20. The electric vehicle probe adapter assembly of claim 19, wherein the body is cylindrical having a first cross-sectional area, and wherein the current probe connection point comprises a portion of the body having a smaller cross-sectional area than the first cross-sectional area to allow the current probe to encircle a conductor in the power signal path.
